(19) United States
(12) Patent Application Publication
(10) Pub. No.: US 2008/0176345 A1
(43) Pub. Date: Jul. 24, 2008

(54) Ebeam inspection for detecting gate dielectric punch through and/or incomplete silicidation or metallization events for transistors having metal gate electrodes

(75) Inventors: Shaofeng Yu, Plano, TX (US); Richard L. Guldi, Dallas, TX (US); Jiong-Ping Lu, Richardson, TX (US); Freidoon Mehrad, Plano, TX (US); Jae Hyun Park, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/655,483

(22) Filed: Jan. 19, 2007

(51) Int. Cl. H01L 21/66

(52) U.S. Cl. 438/17; 257/E21.531

(57) ABSTRACT

Gate dielectric punch through and/or incomplete silicidation or metallization events that may occur during transistor formation are identified. The events are identified just after gate electrodes are formed in order to characterize the degree of faulty transistors for process control purposes and to scrap product if sufficiently defective so that subsequent resources are not unnecessarily expended. An electron beam or ebeam is directed at locations of a workpiece whereon on or more transistors are formed. Electrons that are resultantly emitted from these locations are detected and used to develop respective gray level values (GLV's). Gate dielectric punch through and/or incomplete silicidation or metallization events are identified by finding high or low GLV's relative to neighboring areas.

### FIELD

The disclosure herein relates generally to semiconductor processing, and more particularly to performing an ebeam inspection to detect gate dielectric punch through and/or incomplete silicidation or metallization events for transistors having metal gate electrodes.

### BACKGROUND

Several trends presently exist in the semiconductor and electronics industry. Devices are continually being made smaller, faster and requiring less power. One reason for these trends is that more personal devices are being fabricated that are relatively small and portable, thereby relying on a battery as their primary supply. For example, cellular phones, personal computing devices, and personal sound systems are devices that are in great demand in the consumer market. In addition to being smaller and more portable, personal devices are also requiring increased memory and more computational power and speed. In light of all these trends, there is an ever increasing demand in the industry for smaller and faster transistors used to provide the core functionality of the integrated circuits used in these devices.

Accordingly, in the semiconductor industry there is a continuing trend toward manufacturing integrated circuits (ICs) with higher densities. To achieve high densities, there has been and continues to be efforts toward scaling down dimensions (e.g., at submicron levels) on semiconductor wafers, that are generally produced from bulk silicon. In order to accomplish such high densities, smaller feature sizes, smaller separations between features, and more precise feature shapes are required in integrated circuits (ICs) fabricated on small rectangular portions of the wafer, commonly known as dies. This may include the width and spacing of interconnecting lines, spacing and diameter of contact holes, as well as the surface geometry of various other features (e.g., corners and edges).

It can be appreciated that significant resources go into scaling down device dimensions and increasing packing densities. For example, significant man hours may be required to design such scaled down devices, equipment necessary to produce such devices may be expensive and/or processes related to producing such devices may have to be very tightly controlled and/or be operated under very specific conditions, etc. Accordingly, it can be appreciated that there can be significant costs associated with exercising quality control over semiconductor fabrication, including, among other things, costs associated with discarding defective units, and thus wasting raw materials and/or man hours, as well as other resources, for example. Additionally, since the units are more tightly packed on the wafer, more units are lost when some or all of a wafer is defective and thus has to be discarded. Accordingly, techniques that mitigate yield loss (e.g., a reduction in the number of acceptable or usable units), among other things, would be desirable.

### SUMMARY OF THE INVENTION

The following presents a summary to provide a basic understanding of one or more aspects of the disclosure herein. This summary is not an extensive overview. It is intended neither to identify key or critical elements nor to delineate scope of the disclosure herein. Rather, its primary purpose is merely to present one or more aspects in a simplified form as a prelude to a more detailed description that is presented later.

Gate dielectric punch through and/or incomplete silicidation or metallization events that may occur during transistor formation are identified. The events are identified just after gate electrodes are formed in order to quantify the extent of inoperable device so that data are available for use in improving the process to reduce the level of inoperable devices. In addition, wafers that are sufficiently defective may be scrapped at this point so that subsequent resources are not unnecessarily expended. An electron beam or ebeam is directed at locations of a workpiece whereon on or more transistors are formed. Electrons that are resultantly emitted from these locations are detected and used to develop respective gray level values (GLV's). Gate dielectric punch through and/or incomplete silicidation or metallization events are identified by finding high or low GLV's relative to neighboring areas.

To the accomplishment of the foregoing and related ends, the following description and annexed drawings set forth certain illustrative aspects. Other aspects, advantages and/or features may, however, become apparent from the following detailed description when considered in conjunction with the annexed drawings.

### BRIEF DESCRIPTION OF THE DRAWINGS

FIG. 1 is a cross-sectional view of a transistor having a metal gate electrode.

FIG. 2 is a cross-sectional view of a transistor having a metal gate electrode that is exhibiting a gate dielectric punch through event.

FIG. 3 is a scanning electron microscope (SEM) image of a transistor having a metal gate electrode that is exhibiting a gate dielectric punch through event.

FIG. 4 is a zoomed in SEM image of a gate dielectric punch through event in a transistor that has a metal gate electrode.

FIG. 5 is a cross sectional view of a transistor designed to have a metal gate electrode, but that is exhibiting an incomplete silicidation or metallization event.

FIG. 6 is a SEM image of a transistor designed to have a metal gate electrode, but that is exhibiting an incomplete silicidation or metallization event.

FIG. 7 is a block diagram of a system suitable for determining gate dielectric punch through and/or incomplete silicidation or metallization events with the use of an ebeam.

FIG. 8 is a SEM image illustrating light GLV's indicative of gate dielectric punch through events.

FIG. 9 is a flow diagram illustrating a method for determining gate dielectric punch through or incomplete silicidation or metallization events.

### DETAILED DESCRIPTION OF THE INVENTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one skilled in the art, that one or more aspects described herein may be practiced with a lesser degree of these specific details. In other instances, known structures and devices are shown in block diagram form to facilitate understanding.

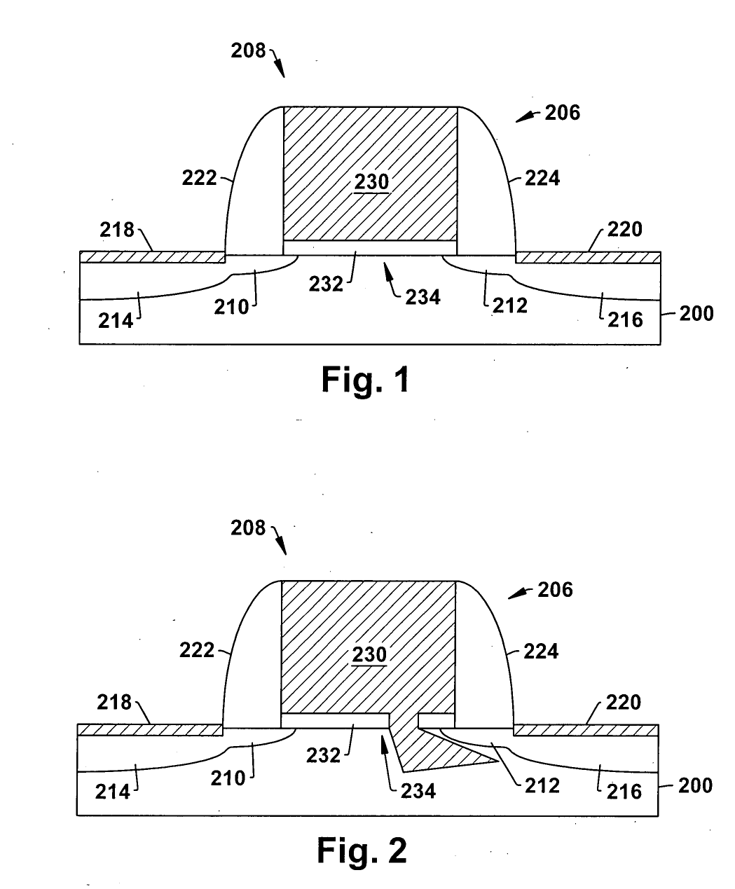

FIG. 1 illustrates a portion of a workpiece or semiconductor substrate 200 having a transistor 206 formed thereon. The transistor 206 generally comprises a gate structure or stack 208, a source extension region 210, a drain extension region 212, a source region 214, a drain region 216, a silicide 218 formed in/on the source region 214, a silicide 220 formed in/on the drain region 216 and left 222 and right 224 sidewall spacers adjacent the gate stack 208, among other things.

The gate stack 208 comprises a gate electrode 230 and gate dielectric 232. The gate electrode 230 generally comprises a polysilicon (or other semiconductor) based material (or a metal based material), and is formed to a thickness of between about 20 nm and about 200 nm, for example. The gate dielectric 232 generally comprises an oxide (or other dielectric) based material and/or a material with high dielectric constant (high-k material), for example, and is relatively thin, being formed to a thickness of between about 0.5 nm and about 20 nm, for example. A channel region 234 is defined in the substrate 200 between the source 210 and drain 212 extension regions and below the gate stack 208.

The transistor “operates”, at least in part, by conducting a current in the channel region 234 between the source 210 and drain 212 extension regions upon the application of certain voltages to the gate electrode 230 and source 214 and drain 216 regions. The transistor 206 may be used as a switch, for example, and may be regarded as being “on”, when a sufficient current is conduced therein, for example. It will be appreciated that the applied voltages are generally originated externally and are transferred to the source 214 and drain 216 regions by the electrically conductive silicide regions 218, 220 formed there-over. A voltage that causes a certain amount of current to flow within the transistor 206 may be regarded as the threshold voltage (Vt) of the transistor.

In the illustrated example, the gate electrode 230 is fully silicided or metallized to facilitate scaling or reducing the size of the transistor. More particularly, dopants may have been added to the gate electrode and annealed to convert the gate electrode from polysilicon to a silicide and/or metal may be added (e.g., deposited) to form all or part of the gate electrode (that may (or may not) initially comprise at least some polysilicon or other non-metallic material(s)). The fully silicided or metal gate electrode 230 facilitates scaling by allowing the effective electrical thickness of the gate dielectric 232 to be reduced by inhibiting the formation of a depletion region at the interface between the gate electrode 230 and the gate dielectric 232. Such a depletion region (which would occur if the gate electrode were polysilicon) is undesirable because, among other things, it reduces the coupling of the gate electrode 230 to the channel region 234, and such adverse effects associated with the depletion region can be exacerbated as the thickness of the gate dielectric 232 is reduced. This can cause the transistor to behave in undesirable manners, such as having a Vt that is too high, for example.

Nevertheless, while the effective electrical gate dielectrics can be made thinner with fully silicided or metal gate electrodes, it can be appreciated that other issues may arise. For example, gate dielectric punch through events from such gates may occur as illustrated in FIG. 2. In this situation, some of the metal and/or dopants may find their way into and/or through the thinner gate dielectric 232 such that some of the substrate 200, channel region 234, source extension region 210, drain extension region 212, source region 214 and/or drain region 216 may become silicided or metallized, thus potentially causing a “short circuit” to the gate electrode 230.

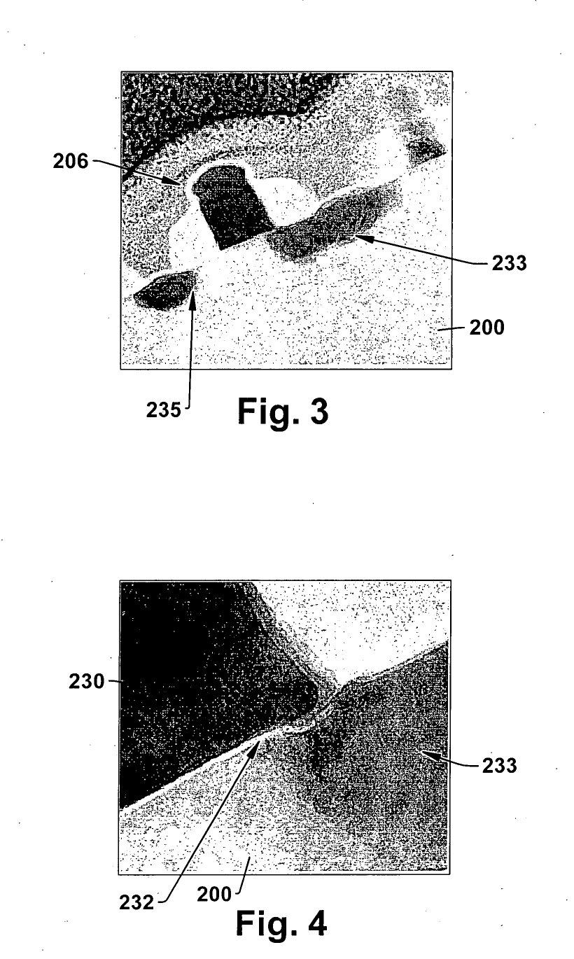

FIG. 3 is a scanning electron microscope (SEM) image of a transistor 206 having a fully silicided or metal gate electrode that is exhibiting a gate dielectric punch through event. It can be seen that silicide or metal material 233 has “leaked” through the gate dielectric 232 and consumed a substantial portion of the substrate 200, channel region 234, drain extension region 212 and drain region 216. It will be appreciated that while the left side 235 of the transistor 206 (e.g., source extension region 210, source region 214 and leftmost part of the channel region 234) appears substantially unaffected in the illustrated example, that such “leakage” can occur in any (one or more) locations of the gate dielectric 232. FIG. 4 is a SEM image of FIG. 3 zoomed in to the vicinity of the gate dielectric 232 where the “leak” appears to occur. It can be appreciated that such leakage has deleterious effects on the transistor by, among other things, affecting the ability of carriers to flow between the source region 214 and the drain region 216.

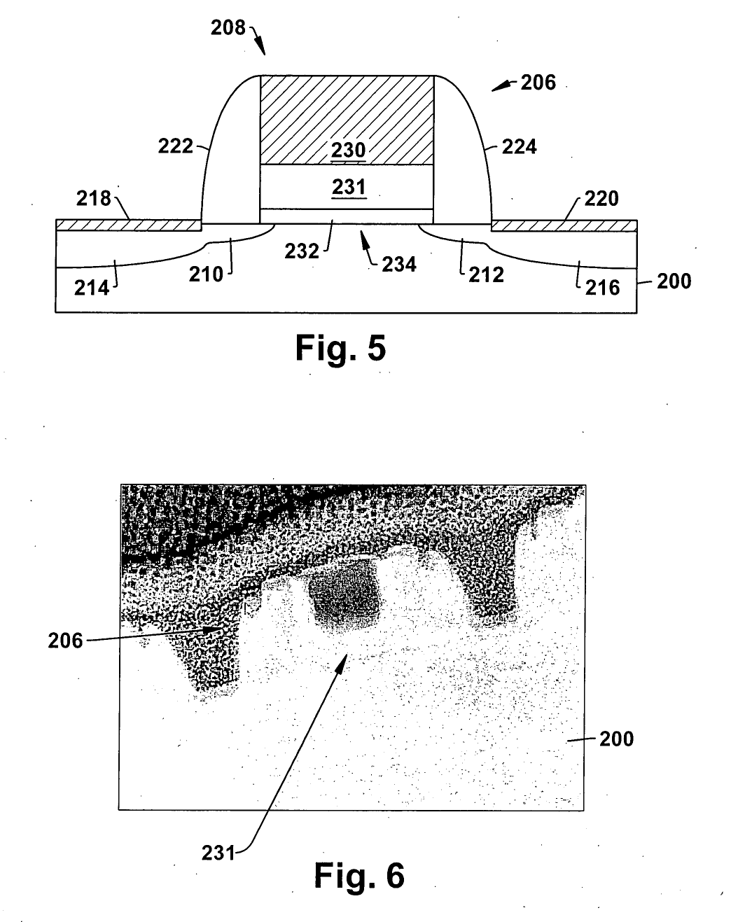

FIG. 5 illustrates another situation that can arise with fully silicided or metal gate electrodes 230, namely less than all of the polysilicon being converted to metal. More particularly, a lower portion 231 of the gate electrode remains as polysilicon. FIG. 6 is a SEM of this situation where a lower portion 231 of the gate electrode has a lighter contrast that is indicative of polysilicon. It can be appreciated that this likewise results in unpredictable or otherwise undesirable transistor behavior, such as by allowing a depletion region to exist at the interface between the gate electrode and the gate dielectric, for example.

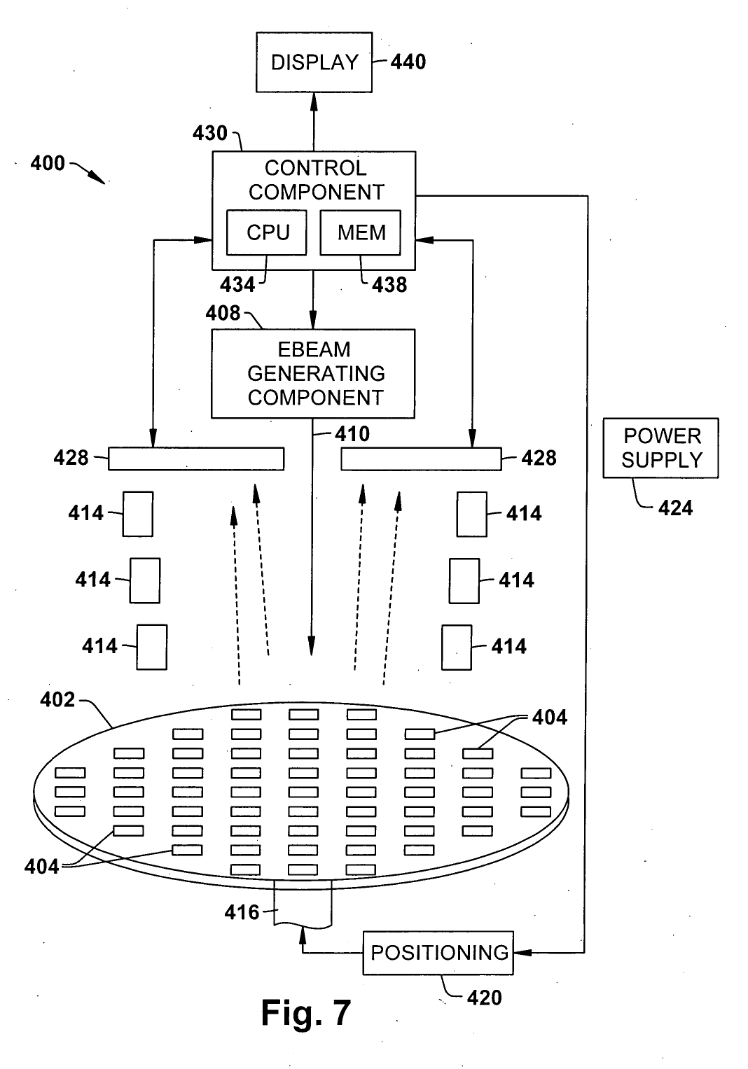

FIG. 7 thus illustrates a system 400 for efficiently inspecting a semiconductor wafer or workpiece 402 (or one or more portions thereof) to detect gate dielectric punch through and/or incomplete silicidation or metallization events. In the illustrated example, the wafer 402 has a plurality of die 404 formed thereon, where one or more copies of integrated circuitry may be formed on respective die 404. The system 400 comprises an electron or ebeam generating component 408 for generating a beam 410 of electrons to direct at the workpiece 402.

It will be appreciated that since different areas (e.g., die) of the workpiece 402 may comprise the same (copies of) integrated circuitry, the beam 410 may be directed at less than all of the workpiece 402 to obtain one or more representative samplings. Further, since transistors may be formed more often or be more densely concentrated in certain areas of the integrated circuitry (e.g., in memory arrays), it may be efficient to sample these areas (rather than other areas or the entirety of the circuitry) to detect gate dielectric punch through and/or incomplete silicidation or metallization events.

In the illustrated example, the system 400 includes one or more guide components 414 (e.g., (electro)magnets) for containing the beam 410, directing it toward the wafer 402, and scanning it across the scan area. Such guide components 414 may, for example, facilitate focusing the beam to a size of between about 0.005 microns and about 0.2 microns, as well as scanning the beam across a portion of the wafer. The workpiece 402 generally resides on a stage (or chuck) 416 that may be operatively coupled to a positioning component 420 that can move the stage (and thus the wafer 402). Accordingly, the beam 410 can be directed at different locations of the wafer 402 by moving the wafer 402 and/or the ebeam (e.g., via the guides 414) relative to one another.

A power supply component 424 is also included in the system 400 to supply power to the components therein. The power supply 424 may, for example, provide a high voltage to the beam generating component 408 for generation of the ebeam 410. The power supply may also be used to provide a bias to the stage 416 to further attract the beam 410 toward the workpiece 402. The guides may likewise be powered by the power supply to direct, contain and/or scan the beam 410. The power supply 424 may be any suitable power supply (e.g., battery, linear, switching).

In operation, when electrons in the beam 410 strike the wafer 402, they will excite secondary electrons (SE) and back scattered electrons (BSE) as well as some other electrons and photons out of that surface. These are emitted from the wafer (as illustrated by arrows in phantom) and detected by detector components 428 situated above the wafer 402. The detector components 428 can be biased (e.g., by the power supply) to attract or repel these particles. The voltage used for attracting or repelling secondary electrons and back scattered electrons is referred to as the “charge control voltage.” In one example, the charge control voltage can be maintained between about −50 volts and about 200 volts to obtain a sufficient degree of resolution.

A control component 430 is also included in the system 400 and can be configured in any suitable manner to control and operate the various components therein. In the example shown, the control system 430 includes a processor 434, such as a microprocessor or CPU, coupled to a memory 438. The processor 434 can be any of a plurality of processors, and the manner in which the processor 434 can be programmed to carry out the functions described herein can be appreciated by one of ordinary skill in the art. The memory 438 included within the control component 430 serves to store, among other things, program code executed by the processor 434 for carrying out operating functions of the system 400 as described herein. The memory 438 may include read only memory (ROM) and random access memory (RAM). The ROM contains among other code the Basic Input-Output System (BIOS) which controls the basic hardware operations of the system 400. The RAM is the main memory into which the operating system and application programs are loaded. The memory 438 may also serve as a storage medium for temporarily storing information such as, for example, tabulated data and algorithms. The memory 438 can also serve as a data store (not shown). For mass data storage, the memory 438 may include a hard disk drive.

The control component 430 receives signals from the detector components 428 indicative of the particles emitted from the wafer 402. These signals can then be used by the control component 430 to generate respective gray level values (GLV's) for the different scanned wafer locations, where the brightness of a GLV for a particular location is a function of the number of electrons emitted from that location. Generally, the more electrons emitted from a location, and thus detected by the detector components 428, the higher or brighter the corresponding GLV.

In one example, the incident ebeam 410 causes more electrons to leave the surface than actually reach it, thus inducing a positive charge on the surface of the workpiece 402. This positive surface potential inhibits SE with low kinetic energy from leaving the surface, which in turn causes fewer electrons to be detected by the detector components 428. Consequently, the resulting images look relatively dark or have a low GLV relative to surrounding areas. Given the opportunity, however, electrons from lower regions in the substrate can neutralize such a positive surface potential so that SE's can escape and be detected by the detection components 428.

A gate dielectric punch through event (FIGS. 2-4) is a situation where electrons from the substrate can neutralize an accumulated surface charge. More particularly, the “punched through” gate dielectric 232 provides an opportunity or pathway for electrons to migrate up to the surface of the workpiece to mitigate a charge accumulated thereon. With the charge neutralized, more electrons are able to leave the workpiece 402 and be detected by the detector components 428 and thus yield a higher or brighter colored GLV.

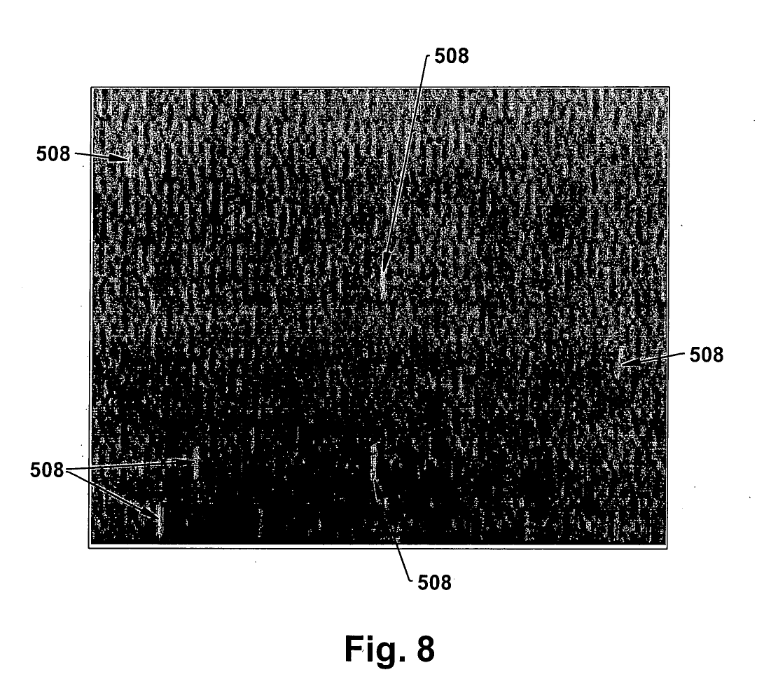

FIG. 8 is a contrast image of a portion of a wafer or workpiece 402 where many transistors are packed relatively close together (e.g., in a memory array). It can be seen that transistors 508 experiencing gate dielectric punch through events can be quickly identified by their higher GLV's (brighter image) relative to surrounding areas.

It can be appreciated that situations where the gate electrode is not fully silicided or metallized can be similarly identified by detecting GLV's that are darker relative to surrounding areas. For example, when the gate electrode is not fully silicided or metallized (FIGS. 5 and 6), any electrons in the substrate that are available to neutralize an accumulated surface charge are separated or otherwise isolated from this charge by the un-silicided portion of the gate electrode. Since the un-silicided portion of the gate electrode blocks these electrons and inhibits neutralization, more SE's are held by the surface charge. Consequently, fewer emitted electrons are detected by the detector components 428, yielding a lower GLV (darker image).

To efficiently detect gate dielectric punch through and/or incomplete silicidation or metallization events and provide a contrast that makes detecting such events relatively apparent, the system 400 can be controlled so that the electrons in the beam 410 have a landing energy of between about 300 volts and about 1500 volts, where the landing energy can be controlled by regulating the total bias between the ebeam generating component 408 and the workpiece 402 or stage 416. Additionally, the beam current may be maintained at between about 30 nano amps and about 800 nano amps, where this corresponds the number of electrons per unit area of the beam and is a function of an excitation voltage applied in the ebeam generating component 408 as well as the composition and/or concentration of gases imparted into the ebeam generating component, among other things.

It will also be appreciated that gate dielectric punch through and/or incomplete silicidation or metallization events can also be detected by comparing determined GLV's to threshold values. For example, upper and lower level gray level threshold values can be stored in the memory 438 of the control component 430, where the upper threshold value establishes a brightness limit and the lower threshold value establishes a darkness limit. Consequently, a gate dielectric punch through event may be identified (e.g., by the control component 430) when a determined gray level value exceeds (e.g., is brighter than) the upper threshold value, and an incomplete silicidation or metallization event may similarly be identified when a determined gray level value falls below (e.g., is darker than) the lower threshold value.

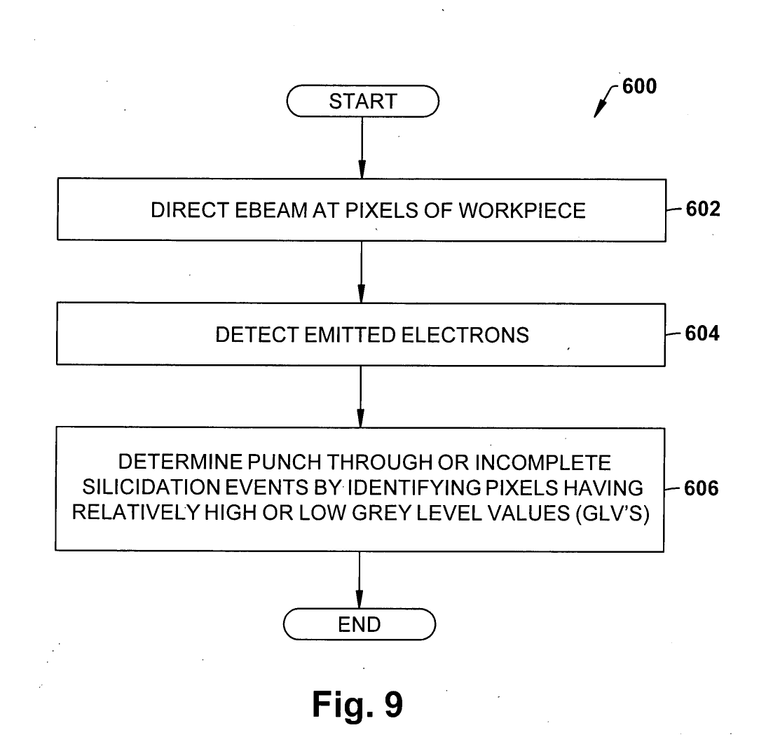

Turning to FIG. 9, a methodology 600 is illustrated for detecting gate dielectric punch through and/or incomplete silicidation or metallization events. While the method 100 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The methodology begins at 602 where an ebeam is directed at regions of a workpiece where transistors are formed. For purposes of efficiency, this may correspond to locations on the workpiece where many transistors are formed, such as in a memory array, for example. The number of electrons emitted as a result of the incident ebeam is then detected or measured for the different locations at 604. Gate dielectric punch through and/or incomplete silicidation or metallization events are then identified by finding gray level values (GLV's) that are high or low relative to surrounding areas, where GLV's are a function of emitted (and detected) electrons. Generally, a gate dielectric punch through event is identified by a relatively high or bright GLV, whereas an incomplete silicidation or metallization event is identified by a relatively low or dark GLV.

It can be appreciated that the workpiece matriculates through many processing stages during the semiconductor fabrication process, and that transistor formation is performed relatively early. Accordingly, the method can be implemented just after transistors as described herein are formed. Identifying gate dielectric punch through and/or incomplete silicidation or metallization events just after the transistors are formed, allows the fabrication process to be re-started or otherwise adapted before additional resources are expended, which can mitigate yield loss. In addition, wafers that are sufficiently defective may be scrapped at this point so that subsequent resources are not unnecessarily expended.

It will be appreciated that, substrate and/or semiconductor substrate as used herein may comprise any type of semiconductor body (e.g., silicon, SiGe, SOI) such as a semiconductor wafer and/or one or more die on a wafer, as well as any other type of semiconductor and/or epitaxial layers associated therewith. Additionally, layers described herein, can be formed in any suitable manner, such as with spin on, sputtering, growth and/or deposition techniques, etc. The term “component” as used herein is intended to include computer-related entities, either hardware, a combination of hardware and software, software, or software in execution. For example, a component may be a process running on a processor, a processor, an object, an executable, a thread of execution, a program, a computer, or any combination thereof. By way of illustration, both an application program running on a server and the server can be components.

Also, equivalent alterations and/or modifications may occur to those skilled in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein.

1. A method for detecting a gate dielectric punch through and/or incomplete silicidation or metallization event during semiconductor processing, comprising:
processing a semiconductor workpiece through a gate electrode silicidation or metallization fabrication stage;
directing an ebeam at a location of the workpiece whereon one or more transistors are formed;
detecting emissions from the location resulting from the incident ebeam;
using the detected emissions to determine a gray level value (GLV) for the location;
identifying a gate dielectric punch through and/or incomplete silicidation or metallization event based upon the determined GLV after formation of the one or more transistors but before completion of processing of the workpiece; and
adapting the processing of the workpiece based on the identification of a gate dielectric punch through and/or incomplete silicidation or metallization event.

2. The method of claim 1, comprising:
comparing the determined GLV to one or more threshold GLV's to identify the gate dielectric punch through and/or incomplete silicidation or metallization event.

3. The method of claim 2, comprising:
comparing the determined GLV to an upper threshold GLV to determine a gate dielectric punch through event.

4. The method of claim 2, comprising:
comparing the determined GLV to a lower threshold GLV to determine an incomplete silicidation or metallization event.

5. The method of claim 3, comprising:
comparing the determined GLV to a lower threshold GLV to determine an incomplete silicidation or metallization event.

6. The method of claim 1, comprising: at least one of:
using a charge control voltage of between about minus 50 volts and about plus 200 volts,
using a landing energy of between about 300 volts and about 1500 volts, and
using a beam current of between about 30 nano amps and about 800 nano amps.

7. The method of claim 5, comprising:
at least one of:
using a charge control voltage of between about minus 50 volts and about plus 200 volts,
using a landing energy of between about 300 volts and about 1500 volts, and
using a beam current of between about 30 nano amps and about 800 nano amps.

8. The method of claim 1, comprising:
comparing the determined GLV to GLV's for neighboring locations to identify the gate dielectric punch through and/or incomplete silicidation or metallization event.

9. The method of claim 8, the gate dielectric punch through event identified by a determined GLV that is brighter than respective GLV's for neighboring locations.

10. The method of claim 8, the incomplete silicidation or metallization event identified by a determined GLV that is darker than respective GLV's for neighboring locations.

11. The method of claim 9, the incomplete silicidation or metallization event identified by a determined GLV that is darker than respective GLV's for neighboring locations.

12. The method of claim 1, comprising:
at least one of:
using a charge control voltage of between about minus 50 volts and about plus 200 volts,
using a landing energy of between about 300 volts and about 1500 volts, and
using a beam current of between about 30 nano amps and about 800 nano amps.

13. A method for detecting gate dielectric punch through and/or incomplete silicidation or metallization events during semiconductor processing, comprising:
directing an ebeam at a location on a workpiece processed through gate electrode silicidation or metallization;
determining whether a punch through and/or incomplete silicidation or metallization event has occurred based upon emissions from the location before completion of processing of the workpiece, where the emissions result from the incident ebeam; and
adapting the processing of the workpiece based on the determination of a ate dielectric punch through and/or incomplete silicidation or metallization event.

14. The method of claim 13, comprising:
detecting emissions from the location resulting from the incident ebeam;
using the detected emissions to determine a gray level value (GLV) for the location, and
identifying a gate dielectric punch through and/or incomplete silicidation or metallization event based upon the determined GLV.

15. The method of claim 14, comprising:
comparing the determined GLV to one or more threshold GLV's to identify the gate dielectric punch through and/or incomplete silicidation or metallization event.

16. The method of claim 15, comprising:
comparing the determined GLV to an upper threshold GLV to determine a gate dielectric punch through event.

17. The method of claim 15, comprising:
comparing the determined GLV to a lower threshold GLV to determine an incomplete silicidation or metallization event.

18. The method of claim 16, comprising:
comparing the determined GLV to a lower threshold GLV to determine an incomplete silicidation or metallization event.

19. The method of claim 14, comprising:
comparing the determined GLV to GLV's for neighboring locations to identify the gate dielectric punch through and/or incomplete silicidation or metallization event.

20. The method of claim 19, comprising:
at least one of:
using a charge control voltage of between about minus 50 volts and about plus 200 volts,
using a landing energy of between about 300 volts and about 1500 volts, and
using a beam current of between about 30 nano amps and about 800 nano amps.

21. The method of claim 1, wherein the adapting comprises at least one of re-starting the processing of the workpiece and terminating the processing of the workpiece before additional processing resources are expended.

22. The method of claim 13, wherein the adapting comprises at least one of re-starting the processing of the workpiece and terminating the processing of the workpiece before additional processing resources are expended.
